(19) United States
(12) Patent Application Publication
(10) Pub. No.: US 2021/0202897 A1
(43) Pub. Date: Jul. 1, 2021

(54) INORGANIC PACKAGE FILM, MANUFACTURING METHOD THEREOF, MANUFACTURING METHOD OF OLED PACKAGE FILM, DISPLAY PANEL, AND DISPLAY DEVICE

(71) Applicants: BOE TECHNOLOGY GROUP CO., LTD., Beijing (CN); ORDOS YUANSHENG OPTOELECTRONICS CO., LTD., Inner Mongolia (CN)

(72) Inventors: Fuyi CUI, Beijing (CN); Quanqin SUN, Beijing (CN); Xu CHEN, Beijing (CN); Ang XIAO, Beijing (CN)

(21) Appl. No.: 16/080,053

(22) PCT Filed: Jan. 5, 2018
(86) PCT No.: PCT/CN2018/071529

§ 371 Date: Aug. 27, 2018

(30) Foreign Application Priority Data
Apr. 18, 2017 (CN) 201710253084.3

(51) Int. Cl. H01L 51/52; H01L 51/56

(52) U.S. Cl. CPC H01L 51/5253; H01L 2251/5338; H01L 51/5256; H01L 51/56

(57) ABSTRACT

An inorganic package film, a manufacturing method thereof, a manufacturing method of an OLED package film, a display panel, and a display device. The manufacturing method includes forming a first inorganic package film on a device to be packaged by a chemical vapor deposition process; and forming a second inorganic package film on the first inorganic package film by an atomic layer deposition process.

### RELATED APPLICATION

The present application is the U.S. national phase entry of PCT/CN2018/071529, with an international filing date of Jan. 5, 2018, which claims the benefit of Chinese Patent Application No. 201710253084.3, filed on Apr. 18, 2017, the entire disclosure of which is incorporated herein by reference.

### FIELD

The present disclosure relates to the field of packaging technologies, and particularly to an inorganic package film, a manufacturing method thereof, a manufacturing method of an OLED package film, a display panel, and a display device.

### BACKGROUND

Electronic devices, especially organic light emitting diode (OLED) devices, are particularly sensitive to moisture and oxygen in the air, so OLED devices need to be packaged to ensure device performance and lifetime. With the advent of flexible OLED display panels, thin film packaging technology has been proposed accordingly, which on the one hand requires a package structure to have the ability to block moisture and oxygen, and on the other hand requires the package structure to have flexible and bendable characteristics. Consequently, conventional rigid package structures fail to meet the demand, and a new package form represented by a thin film package structure thus appears.

At present, most of the thin film package structures are structures in which an organic film layer and an inorganic film layer are alternately arranged, and the inorganic film layer usually includes an inorganic film layer such as SiNₓ\SiO₂ prepared by a chemical vapor deposition process. However, the existing OLED display panel can only be subjected to a low temperature process, while the chemical vapor deposition process only achieves good compactness when forming a film at high temperatures. Further, due to other indexes such as stress, an inorganic film layer prepared by such process has poor compactness and even involves micropores, making it have poor insulating property and ability to block moisture and oxygen.

In view of the above, there is a need in the art for a further improved inorganic package film.

### SUMMARY

It is an object of the present disclosure to provide an improved inorganic package film, a method for manufacturing an OLED package film, and a corresponding device, which can at least partially alleviate or eliminate one or more of the problems mentioned above.

An exemplary embodiment of the present disclosure provides a method for manufacturing an inorganic package film, including forming a first inorganic package film on a device to be packaged by a chemical vapor deposition process; and forming a second inorganic package film on the first inorganic package film by an atomic layer deposition process.

According to some embodiments, the second inorganic package film completely covers the first inorganic package film.

According to some embodiments, a material forming the first inorganic package film is different from a material forming the second inorganic package film.

According to some embodiments, the material of the second inorganic package film is one or a combination of the following materials: alumina Al₂O₃, titanium oxide TiO and silicon dioxide SiO₂.

According to some embodiments, temperatures of the chemical vapor deposition process and the atomic layer deposition process range from 70° C. to 100° C.

According to some embodiments, the second inorganic package film has a thickness ranging from 0.03 μm to 0.1 μm.

According to some embodiments, the inorganic package film has a thickness no greater than 0.5 μm.

Another exemplary embodiment of the present disclosure provides a method for manufacturing an OLED package film, including respectively forming an organic package film and an inorganic package film which are alternately disposed. The inorganic package film is manufactured by the above method provided by embodiments of the present disclosure.

Another exemplary embodiment of the present disclosure provides an inorganic package film including a first inorganic package film formed by a chemical vapor deposition process; and a second inorganic package film located on the first inorganic package film and formed by an atomic layer deposition process.

According to some embodiments, the second inorganic package film completely covers the first inorganic package film.

According to some embodiments, the second inorganic package film has a thickness ranging from 0.03 μm to 0.1 μm.

According to some embodiments, the inorganic package film has a thickness no greater than 0.5 μm.

Another exemplary embodiment of the present disclosure provides an OLED display panel including a light emitting device in a display area; and a package film located on the light emitting device and configured to package the light emitting device. The package film includes an organic package film and any of the above inorganic package films provided by embodiments of the present disclosure which are alternately disposed.

A further exemplary embodiment of the present disclosure provides a display device including any of the above OLED display panels provided by embodiments of the present disclosure

### BRIEF DESCRIPTION OF DRAWINGS

FIG. 1 is a flow chart of a method for manufacturing an inorganic package film provided by an embodiment of the present disclosure;

FIG. 2 is a sectional view of an inorganic package film provided by an embodiment of the present disclosure;

FIG. 3a is a sectional view of an OLED package film provided by an embodiment of the present disclosure;

FIG. 3b is a sectional view of another OLED package film provided by an embodiment of the present disclosure.

### DETAILED DESCRIPTION

The technical solutions in embodiments of the present disclosure will be described below in a clear and complete manner with reference to the accompanying drawings in the embodiments of the present disclosure. It is obvious that the described embodiments are only a part of the embodiments of the present disclosure, rather than all of them. All other embodiments obtained by those skilled in the art based on the embodiments of the present disclosure without spending inventive efforts fall within the scope of the present disclosure.

Thicknesses and shapes of film layers in the drawings are not drawn true to scale, and are merely intended to illustrate the present disclosure.

In the method for manufacturing an inorganic package film provided by an embodiment of the present disclosure, the inorganic package film is no longer formed only by a chemical vapor deposition process, but two inorganic package film layers are formed separately by a chemical vapor deposition process and an atomic layer deposition process. Thanks to the small film formation unit of the atomic layer deposition process, the formed film layer has higher compactness and can thus fill the micropores present in the inorganic package film prepared by the chemical vapor deposition process, which can improve the insulating property of the inorganic film layer and the ability thereof to block moisture and oxygen, thereby improving the packaging effect.

The method for manufacturing an inorganic package film provided by an embodiment of the present disclosure will be described in detail below.

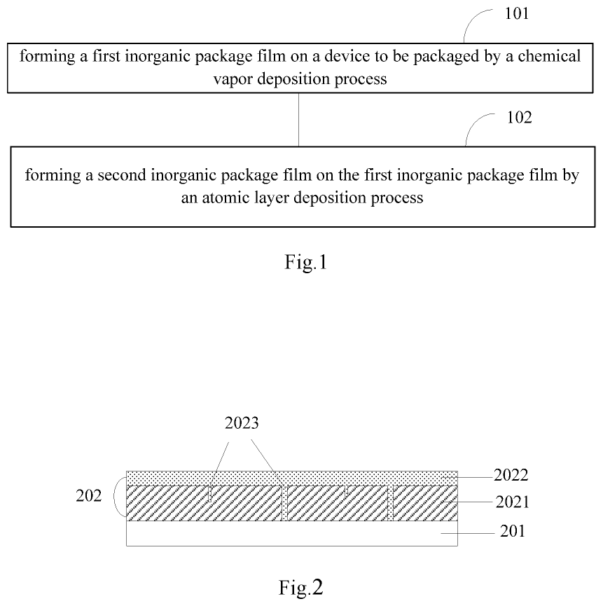

FIG. 1 is a flow chart illustrating the steps of a method for manufacturing an inorganic package film provided by an embodiment of the present disclosure.

As shown in FIG. 1, the manufacturing method includes, in step 101, forming a first inorganic package film on a device to be packaged by a chemical vapor deposition process.

The manufacturing method further includes, in step 102, forming a second inorganic package film on the first inorganic package film by an atomic layer deposition process.

FIG. 2 schematically illustrates a sectional view of an inorganic package film provided by an embodiment of the present disclosure. As shown in FIG. 2, the inorganic package film includes an inorganic package film 202 formed on a device 201 to be packaged, wherein the inorganic package film 202 includes a first inorganic package film 2021 and a second inorganic package film 2022. The first inorganic package film 2021 is formed by a chemical vapor deposition process.

Since the first inorganic package film 2021 is formed by a chemical vapor deposition process, the resulting first inorganic package film 2021 has poor compactness and even involves micropores 2023, making it have poor insulating property and ability to block moisture and oxygen. Therefore, a second inorganic package film 2022 is formed on the first inorganic package film 2021 by an atomic layer deposition process. Thanks to the small film formation unit of the atomic layer deposition process, the formed film layer has higher compactness and can thus fill the micropores 2023 present in the first inorganic package film 2021 prepared by the chemical vapor deposition process, which can improve the insulating property of the inorganic package film 202 and the ability thereof to block moisture and oxygen, thereby improving the packaging effect.

In certain exemplary embodiments, in order to make the packaging effect of the inorganic package film 202 better, in an exemplary embodiment, the second inorganic package film 2022 may completely cover the first inorganic package film 2021, thereby enabling the second inorganic package film 2022 to better fill the micropores in the first inorganic package film 2021. At the same time, the packaging effect is not affected by possible formation of steps.

Since films formed by different inorganic materials are different in compactness, insulating property and ability to block moisture and oxygen, and different manufacturing processes also have different requirements on the manufacturing material, manufacturing materials may be selected for the first inorganic package film and the second inorganic package film in the above inorganic package film as actually required. For example, in an exemplary embodiment, the material forming the first inorganic package film is different from the material forming the second inorganic package film.

In view of the requirements of the atomic layer deposition process, in particular, the material of the second inorganic package film may be one or a combination of the following materials: alumina Al₂O₃, titanium oxide TiO and silicon dioxide SiO₂. The material of the first inorganic package film may be arbitrarily selected from inorganic materials which can be prepared by a chemical vapor deposition process and can block moisture and oxygen, which is not limited herein.

Upon implementation, since an OLED device can only be subjected to a low temperature process, in an exemplary embodiment, temperatures of the atomic layer deposition process and the chemical vapor deposition process range from 70° C. to 100° C. Since a film formed by the chemical vapor deposition process at high temperatures has good compactness, and a film formed at low temperatures has poor compactness and easily involves micropores, the second inorganic package film prepared by the atomic layer deposition process can fill the micropores present in the inorganic package film prepared by the chemical vapor deposition process, which can improve the insulating property of the entire inorganic package film and the ability thereof to block moisture and oxygen, thereby improving the packaging effect of the inorganic package film.

In fact, in an exemplary embodiment, the inorganic package film may also be formed only by the atomic layer deposition process. However, since the atomic layer deposition process has a relatively slow film formation rate and can hardly meet the demand for mass production, a combined process of the chemical vapor deposition process and the atomic layer deposition process according to embodiments of the present disclosure achieves nano-scale atomic film formation by on the one hand taking advantage of high-speed film formation of the chemical vapor deposition process and on the other hand using the atomic layer deposition process, which repairs the film formation deficiency of the low temperature chemical vapor deposition, thereby obtaining an excellent composite film and achieving the packaging requirements of the flexible packaging.

Correspondingly, an embodiment of the present disclosure further provides a method for manufacturing an OLED package film, including respectively forming an organic package film and an inorganic package film which are alternately disposed. The inorganic package film is manufactured by any of the above methods for manufacturing an inorganic package film provided by embodiments of the present disclosure. For the implementation of the method for manufacturing an OLED package film, reference may be made to the above embodiments of the method for manufacturing an inorganic package film, and the repeated description is omitted.

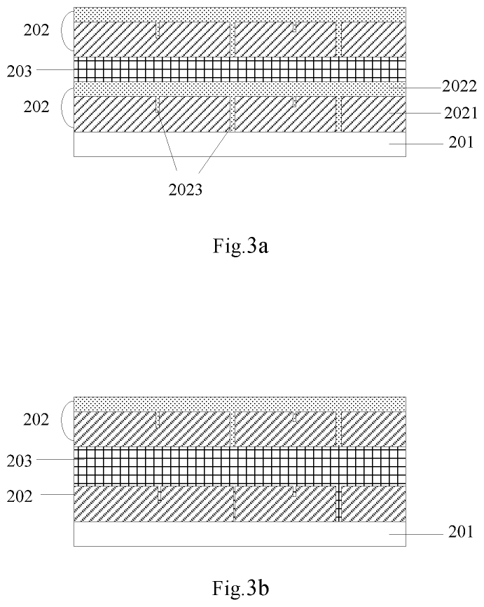

FIG. 3a schematically illustrates a sectional view of an OLED package film provided by an embodiment of the present disclosure. As shown in FIG. 3a, the OLED package film includes an organic package film 203 and an inorganic package film 202 which are alternately disposed. It is to be noted that although the OLED package film shown in FIG. 3a illustratively includes only two inorganic package films 202 and an organic package film 203 disposed between the two inorganic package films 202, the OLED package film may include any number of organic package films 203 and inorganic package films 202 alternately disposed. In such an OLED package film, each inorganic package film 202 is formed by a combined process of the chemical vapor deposition process and the atomic layer deposition process described above.

Alternatively, when the OLED package film includes a plurality of inorganic package films, in order to increase the film formation rate, only one or more of the inorganic package films may be formed by a combined process of the chemical vapor deposition process and the atomic layer deposition process described above as needed, while other inorganic package films may be formed by the chemical vapor deposition process with a faster film formation rate.

FIG. 3b schematically illustrates a sectional view of another OLED package film provided by an embodiment of the present disclosure. As shown in FIG. 3b, the outermost inorganic package film 202 in the OLED package film is formed by a combined process of the chemical vapor deposition process and the atomic layer deposition process described above, and other inorganic package films 202 are formed only by the chemical vapor deposition process.

An embodiment of the present disclosure further provides an inorganic package film including, as shown in FIG. 2, a first inorganic package film 2021 formed by a chemical vapor deposition process, and a second inorganic package film 2022 disposed on the first inorganic package film 2021 and formed by an atomic layer deposition process. For the implementation of the inorganic package film, reference may be made to the above embodiments of the method for manufacturing an inorganic package film, and the repeated description is omitted.

Further, an embodiment of the present disclosure further provides an OLED display panel including a light emitting device disposed in a display area, and a package film disposed on the light emitting device and configured to package the light emitting device. The package film includes an organic package film and the above inorganic package film provided by embodiments of the present disclosure which are alternately disposed. For the implementation of the OLED display panel, reference may be made to the above embodiments of the inorganic package film, and the repeated description is omitted.

In the conventional technique of preparing an inorganic package film only by a chemical vapor deposition process, in order to make the inorganic package film's insulating property and ability to block moisture and oxygen satisfactory, it is usually brought to a certain thickness, generally at least about 0.8 μm. In contrast, in embodiments of the present disclosure, since the second inorganic package film formed by the atomic layer deposition process has good compactness, the thickness of the inorganic package film can be appropriately reduced. For example, the thickness of the inorganic package film is not more than 0.5 μm. Therefore, the thickness of the OLED display panel may be further reduced to meet the needs of an ultra-thin display screen.

In an exemplary embodiment, considering that the atomic layer deposition process has a slow film formation rate in a low temperature environment, the second inorganic package film can be made very thin in order to meet the demand for mass production, as long as the formed second inorganic layer has satisfactory insulating property and ability to block moisture and oxygen. For example, in some exemplary embodiments, the second inorganic package film has a thickness ranging from 0.03 μm to 0.1 μm.

An embodiment of the present disclosure further provides a display device including the above OLED display panel provided by embodiments of the present disclosure. For the implementation of the display device, reference may be made to the above embodiments of the OLED display panel, and the repeated description is omitted.

In summary, in the present disclosure, at the time of manufacturing an inorganic package film, two inorganic package films are formed separately by a chemical vapor deposition process and an atomic layer deposition process. Therefore, compared to the inorganic package film formed only by the chemical vapor deposition process, thanks to the small film formation unit of the atomic layer deposition process, the formed inorganic package film layer has higher compactness and can thus fill the micropores present in the inorganic package film prepared by the chemical vapor deposition process, which can further improve the insulating property of the inorganic film layer and the ability thereof to block moisture and oxygen, thereby improving the packaging effect.

Obviously, those skilled in the art can make various modifications and variations to the present disclosure without departing from the spirit and scope thereof. In this way, if these modifications and variations to the present disclosure pertain to the scope of the claims of the present disclosure and equivalent technologies thereof, the present disclosure also intends to encompass these modifications and variations.

1. A method for manufacturing an inorganic package film, comprising:
forming a first inorganic package film on a device to be packaged by a chemical vapor deposition process;
forming a second inorganic package film on the first inorganic package film by an atomic layer deposition process.

2. The method according to claim 1, wherein the second inorganic package film completely covers the first inorganic package film.

3. The method according to claim 1, wherein a material forming the first inorganic package film is different from a material forming the second inorganic package film.

4. The method according to claim 3, wherein the material of the second inorganic package film is one or a combination of the following materials:
alumina Al₂O₃, titanium oxide TiO and silicon dioxide SiO₂.

5. The method according to claim 1, wherein temperatures of the chemical vapor deposition process and the atomic layer deposition process range from 70° C. to 100° C.

6. The method according to claim 1, wherein the second inorganic package film has a thickness ranging from 0.03 μm to 0.1 μm.

7. The method according to claim 1, wherein the inorganic package film has a thickness no greater than 0.5 μm.

8. A method for manufacturing an OLED package film, comprising:
respectively forming an organic package film and an inorganic package film which are alternately disposed,
wherein the inorganic package film is manufactured by the method according to claim 1.

9. An inorganic package film comprising:
a first inorganic package film formed by a chemical vapor deposition process; and
a second inorganic package film located on the first inorganic package film and formed by an atomic layer deposition process.

10. The inorganic package film according to claim 9, wherein the second inorganic package film completely covers the first inorganic package film.

11. The inorganic package film according to claim 9, wherein the second inorganic package film has a thickness ranging from 0.03 μm to 0.1 μm.

12. The inorganic package film according to claim 9, wherein the inorganic package film has a thickness no greater than 0.5 μm.

13. An OLED display panel comprising:
a light emitting device in a display area; and
a package film located on the light emitting device and configured to package the light emitting device,
wherein the package film comprises an organic package film and the inorganic package film according to claim 9 which are alternately disposed.

14. A display device comprising the OLED display panel according to claim 13.

15. The method according to claim 2, wherein a material forming the first inorganic package film is different from a material forming the second inorganic package film.

16. The method according to claim 15, wherein the material of the second inorganic package film is one or a combination of the following materials:
alumina Al₂O₃, titanium oxide TiO and silicon dioxide SiO₂.

17. The method according to claim 8, wherein the second inorganic package film completely covers the first inorganic package film.

18. The method according to claim 8, wherein a material forming the first inorganic package film is different from a material forming the second inorganic package film.

19. The method according to claim 18, wherein the material of the second inorganic package film is one or a combination of the following materials:
alumina Al₂O₃, titanium oxide TiO and silicon dioxide SiO₂.

20. The method according to claim 8, wherein temperatures of the chemical vapor deposition process and the atomic layer deposition process range from 70° C. to 100° C.
